(19) United States
(12) Patent Application Publication
(10) Pub. No.: US 2009/0237879 A1
(43) Pub. Date: Sep. 24, 2009

(54) ELECTRONIC DEVICE HAVING A HEAT DISSIPATING MECHANISM

(76) Inventor: Chun-Ju LIN, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/076,454

(22) Filed: Mar. 19, 2008

(51) Int. Cl. H05K 7/20

(52) U.S. Cl. 361/692; 361/697

(57) ABSTRACT

An electronic device having a heat-dissipating mechanism includes a housing and a cooling device. The housing is provided with an intake hole and a plurality of exhausting holes. The interior of the housing is provided with a heat-dissipating fan. The cooling device includes a cooling chip, at least one cooler and at least one heater. The cooling chip has a cold end and a hot end opposite to each other. The cooler is connected to the cold end of the cooling chip. The cooler is arranged at one side of the heat-dissipating fan in the direction of airflow generated by the heat-dissipating fan. The heater is connected to the hot end of the cooling chip. The heater is located outside the housing and corresponds to the locations of the exhausting holes. Via this arrangement, the temperature within the housing of the electronic device can be reduced efficiently.

### BACKGROUND OF THE INVENTION

1. Field of the Invention

The present invention relates to an electronic device having a heat-dissipating mechanism, and in particular to an electronic device having a heat-dissipating mechanism that includes a cooling chip to dissipate heat efficiently.

2. Description of Related Art

Heat-dissipating fans are usually fitted to the housings of common electronic devices (such as a power supply or computer host). Via the heat-dissipating fan, air can be introduced into the housing to dissipate the heat outside the housing, thereby preventing the electronic device from suffering damage due to the excessively high temperature thereof.

The conventional electronic device utilizes a heat-dissipating fan to introduce the external air in the housing. However, the external air may not always have a temperature low enough to cool the electronic device sufficiently. Especially in summer, the temperature of the external air is high.

Consequently, because of the above technical defects, the inventor keeps on carving unflaggingly through wholehearted experience and research to develop the present invention, which can effectively improve the defects described above.

### SUMMARY OF THE INVENTION

The object of the present invention is to provide an electronic device having a heat-dissipating mechanism that a cooling chip is provided therein to reduce the internal temperature efficiently.

In order to achieve the above objects, the present invention provides an electronic device having a heat-dissipating mechanism, which includes: a housing provided with an intake hole and a plurality of exhausting holes, the interior of the housing being provided with a heat-dissipating fan to correspond to the intake hole; and a cooling device.

The cooling device comprises: a cooling chip having a cold end and a hot end; at least one cooler connected to the cold end of the cooling chip, the cooler being arranged at one side of the heat-dissipating fan in the direction of airflow generated by the heat-dissipating fan; and at least one heater connected to the hot end of the cooling chip, the heater being located outside the housing and corresponding to the locations of the exhausting holes.

The present invention has advantageous effects as follows. Via the cooling chip, the temperature within the housing of the electronic device can be reduced efficiently. Further the heat generated by the cooling chip can be dissipated by the heat-dissipating fan of the electronic device. Therefore, it is unnecessary to mount an additional heat-dissipating fan, thereby reducing the production cost.

Further, the cooling chip and the heater are arranged outside the housing, thereby saving the internal space and exhibiting a better heat-dissipating efficiency.

In order to further understand the characteristics and technical contents of the present invention, a detailed description relating thereto will be made with reference to the accompanying drawings. However, the drawings are illustrative only, but not used to limit the scope of the present invention.

### BRIEF DESCRIPTION OF THE DRAWINGS

FIG. 1 is an assembled perspective view showing the first embodiment of the present invention;

FIG. 2 is an assembled perspective view showing the first embodiment of the present invention taken along another viewing angle;

FIG. 3 is a side view showing the first embodiment of the present invention with one side wall of the housing not shown;

FIG. 4 is an assembled perspective view showing the cooling device of the first embodiment of the present invention;

FIG. 5 is a rear view showing the cooling device of the first embodiment of the present invention;

FIG. 6 is an exploded view showing the casing of the cooling device of the first embodiment of the present invention;

FIG. 7 is an assembled perspective view showing the second embodiment of the present invention;

FIG. 8 is an assembled perspective view showing the second embodiment of the present invention being connected to the housing body; and

FIG. 9 is a side view showing the second embodiment of the present invention being connected to the housing body with one side wall of the housing not shown.

### DETAILED DESCRIPTION OF THE PREFERRED EMBODIMENTS

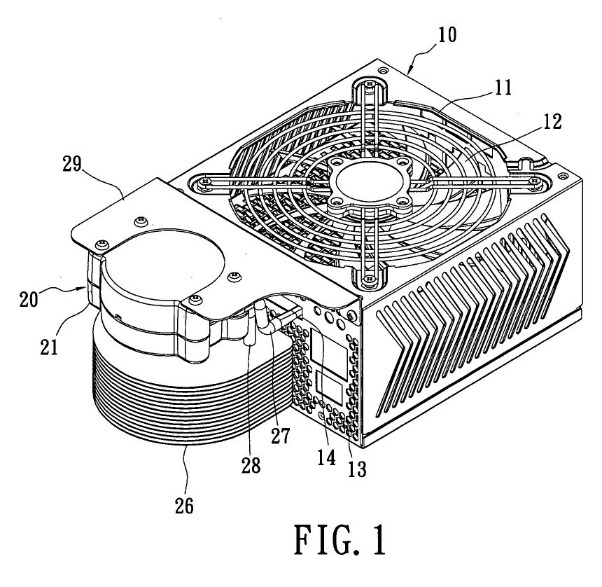

Please refer to FIGS. 1 to 3, which show the electronic device having a heat-dissipating mechanism of a first embodiment in accordance with the present invention. For example, the electronic device may be a power supply, a backup power supply, personal computer, an industrial computer, server, uninterruptible power supply, disk array external box, external hard disk box, external optical disk, keyboard, housing of a heat-dissipating plate of a notebook computer, projector or medical measurement and detection instruments.

The present embodiment takes a power supply as an example of the electronic device, but it is not limited thereto. The electronic device includes a housing 10 and a cooling device 20.

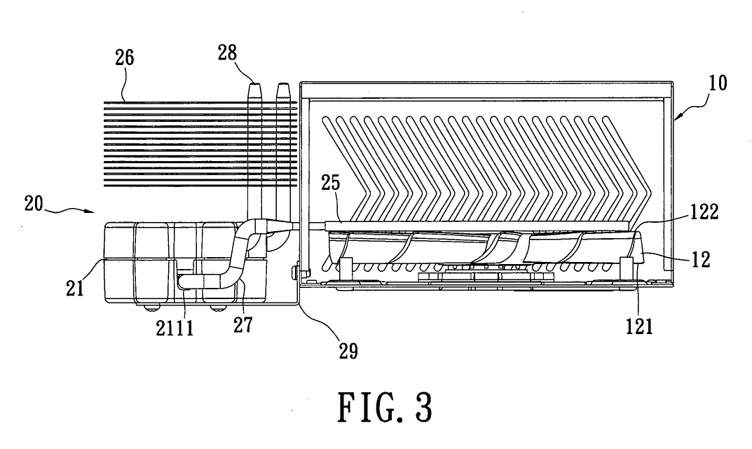

The housing 10 is square and an end surface thereof is provided with an intake hole 11 for allowing the air outside the housing 10 to enter. The interior of the housing 10 is provided with a heat-dissipating fan 12 to correspond to the intake hole 11. The heat-dissipating fan 12 has an intake end 121 corresponding to the intake hole 11 of the housing 10, and an exhausting end 122 opposite to the intake end 121 (FIG. 3).

The side surface of the housing 10 is provided with a plurality of exhausting holes 13. When the heat-dissipating fan 12 rotates, the air outside the housing 10 will be drawn in the housing 10 via the intake hole 11, and then be exhausted to the outside via the exhausting holes 13.

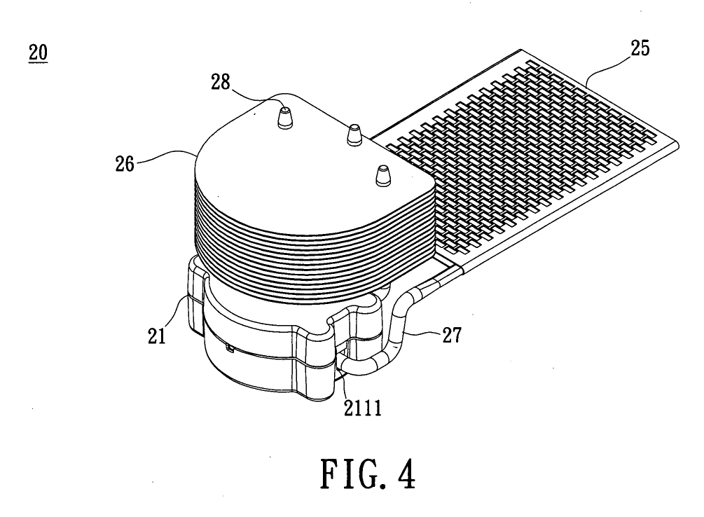

Please refer to FIGS. 4 to 6. The cooling device 20 comprises a casing 21, a cooling chip 22, a first heat-conducting block 23, a second heat-conducting block 24, at least one cooler 25, at least one heater 26, two first heat pipes 27, and three second heat pipes 28. The cooling device 20 can drive the cooling chip 22 directly via the power provided by the housing 10.

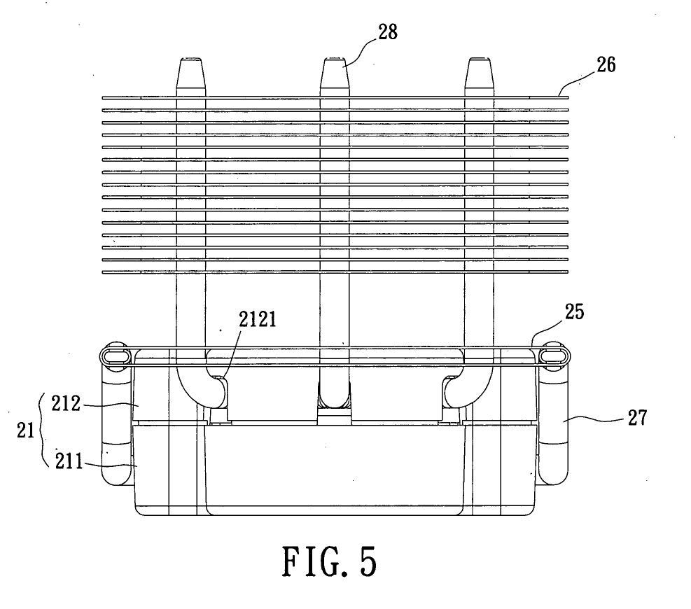

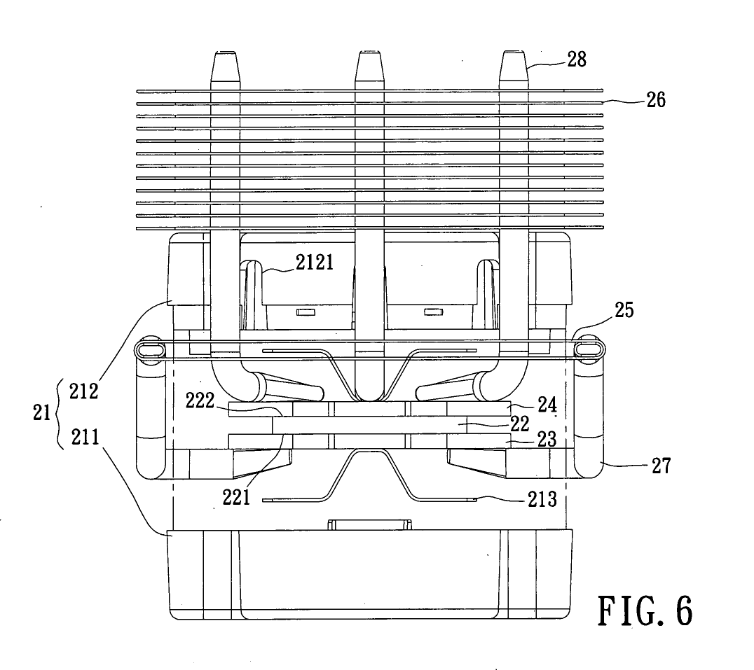

In the present embodiment, the casing 21 is designed into two pieces, which comprises a first piece 211 and a second piece 212 assembled with the first piece 211 (also refer to FIG. 6). The cooling chip 22, the first heat-conducting block 23 and the second heat-conducting block 24 are provided between the first piece 211 and the second piece 212 (that is, within the casing 21). The casing 21 is provided with first through holes 2111 (FIG. 4) and second through holes 2121 (FIG. 5) respectively for allowing the first heat pipes 27 and second heat pipes 28 to pass through.

After being supplied with electricity, the cooling chip 22 can develop a cold end 221 and a hot end 222 (FIG. 6). The hot end 222 and the cold end 221 are arranged in the up-and-down direction and opposite to each other. The first heat-conducting block 23 and the second heat-conducting block 24 are arranged on the cold end 221 and the hot end 222 of the cooling chip 22 respectively.

Elastic pieces 213 are provided between the casing 21 of the cooling device 20 and the first heat-conducting block 23 and the second heat-conducting block 24 (FIG. 6). In this way, the first heat-conducting block 23 and the second heat-conducting block 24 can abut against the cold end 221 and the hot end 222 of the cooling chip 22 tightly.

In the present embodiment, the cooler 25 is a metallic net, but it is not limited thereto. The cooler 25 may be a heat-dissipating fins assembly. The cooler 25 is arranged at one side of the heat-dissipating fan 12 adjacent to the exhausting end 122 along the direction of airflow generated by the heat-dissipating fan 12 (FIG. 3), and is located within the housing 10.

In the present embodiment, the heater 26 is a heat-dissipating fins assembly, but it is not limited thereto. The heater 26 is located outside the housing 10 to correspond to the locations of the exhausting holes 13.

One end of each first heat pipe 27 is connected to the surface of the first heat-conducting block 23, thereby connecting to the cold end 221 of the cooling chip 22. The other end of the first heat pipe 27 is connected to the cooler 25, so that the cooler 25 can be connected with the cold end 221 of the cooling chip 22 via the first heat pipe 27 and the heat-conducting block 23.

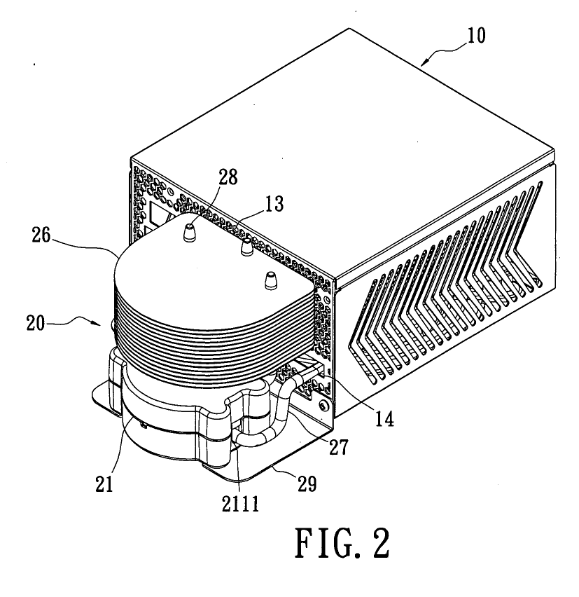

One side of the housing 10 is provided with at least one through holes 14 to correspond to the first heat pipes 27 (FIG. 2). The other end of the first heat pipe 27 extends into the housing 10 via the through hole 14.

One end of each second heat pipe 28 is connected to the second heat-conducting block 24 and in turn connected to the hot end 222 of the cooling chip 22. The other end of the second heat pipe 28 is connected to the heater 26, so that the heater 26 can be connected with the hot end 222 of the cooling chip 22.

A support 29 is provided between the casing 21 of the cooling device 20 and the housing 10, thereby supporting the casing 21 of the cooling device 20 (FIG. 2). The support 29 is assembled with the casing 21 of the cooling device 20 and the housing 10 via screw elements or other fixing means.

Please refer to FIG. 3. When the present invention is in use, the cold end 221 of the cooling chip 22 cooperates with the first heat-conducting block 23, the first heat pipes 27 and the cooler 25, thereby generating cold air around the cooler 25. When the heat-dissipating fan 12 rotates, the cold air can be blown toward the electronic elements (not shown) in the housing 10 directly. In this way, the temperature of the electronic elements can be reduced by means of the cold air, thereby achieving a better heat-dissipating effect.

At this time, the hot end 222 of the cooling chip 22 cooperates with the second heat-conducting block 24, the second heat pipes 28 and the heater 26, thereby conducting the heat generated by the cooling chip 22 to the heater 26. The above-mentioned cold air is exhausted via the exhausting holes 13 of the housing 10 (FIG. 2) and blows toward the heater 26. Also, the heat generated in the housing 10 and by the cooling chip 22 can be dissipated outside.

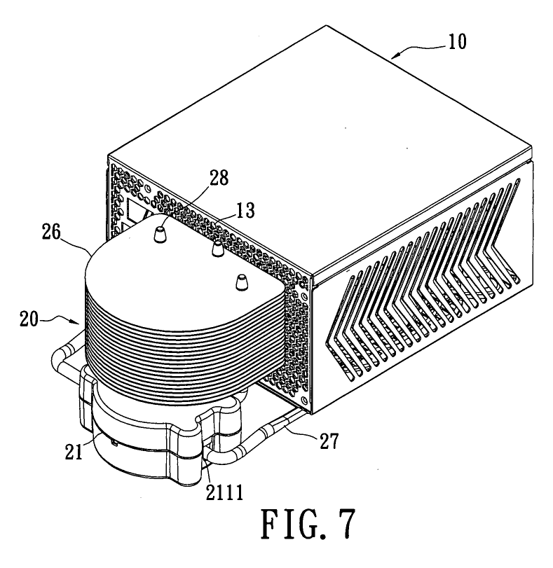

Please refer to FIG. 7, which shows a second embodiment of the present invention. The difference between the second embodiment and the first embodiment is as follows.

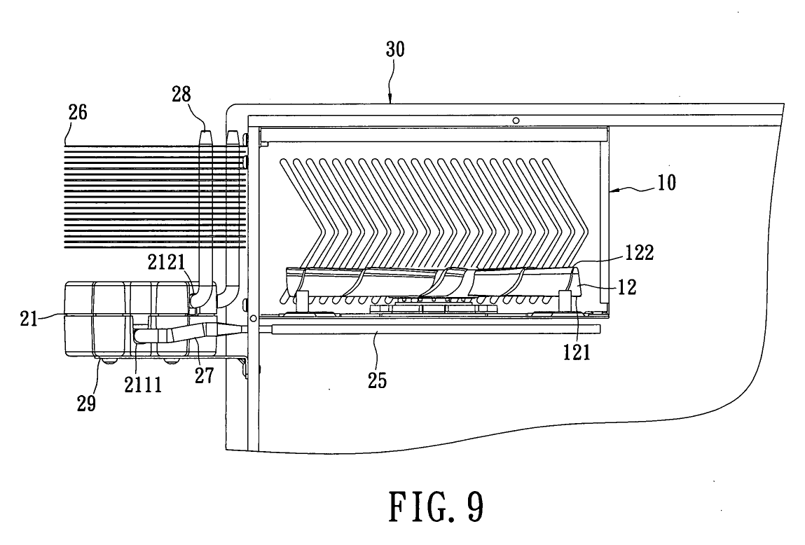

The cooler 25 is provided at one side of the heat-dissipating fan 12 adjacent to the intake end 121 along the direction of the airflow generated by the heat-dissipating fan 12 (FIG. 9), and is located outside the housing 10. Via this arrangement, it is unnecessary to provide a through hole 14 on the housing 10 like the first embodiment, and the second heat pipes 28 do not extend into the housing 10.

The electronic device of the present invention can be further provided with an adjusting device (not shown) that is connected to the cooling device 20, thereby setting the operating time of the cooling device 20 or performing the setting of the temperature.

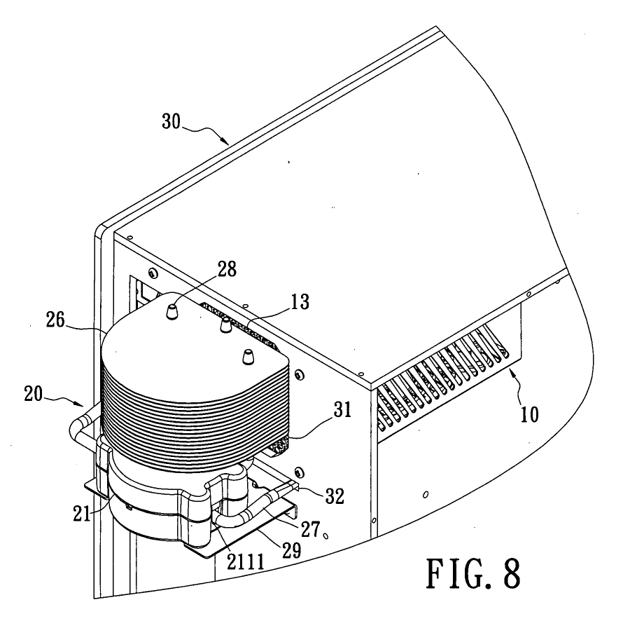

With reference to FIGS. 8 and 9, which show the second embodiment of the present invention being arranged in a housing body 30. Of course, the electronic device of the first embodiment can be combined with the housing body 30.

The housing body 30 is provided with an open hole 31 corresponding to the exhausting hole 13 of the housing 10 (FIG. 8). The exhausting holes 13 are exposed to the open hole 31.

One side of the housing body 30 is provided with at least one through holes 32 to correspond to the first heat pipe 27. The other end of the first heat pipe 27 extends into the housing body 30 via the through hole 32. The cooler 25 is located in the housing body 30. The cooler 25 is provided at one side of the heat-dissipating fan 12 adjacent to the intake end 121, and is located outside the housing 10.

A support 29 is also provided between the casing 21 of the cooling device 20 and the housing body 30, thereby supporting the casing 21 of the cooling device 20.

In use, similarly, the cold end 221 of the cooling chip 22 cooperates with the first heat-conducting block 23, the first heat pipes 27 and the cooler 25, thereby generating cold air around the cooler 25. The cold air is introduced into the housing 10 via the heat-dissipating fan 12 and the intake hole 11 (FIG. 1), so that the temperature of the electronic elements (not shown) inside the housing 10 can be reduced by means of the cold air, thereby achieving a better heat-dissipating effect.

Similarly, the heat of the heater 26 can be taken away by the cold air exhausted from the exhausting holes 13 of the housing 10 (FIG. 2). Therefore, the present invention can produce some advantageous effects as follows.

(1) With the provision of the cooling chip, the temperature inside the housing of the electronic device can be reduced efficiently.

(2) The cooling chip and the heater are located outside the housing. Therefore, the space within the housing may not be occupied, thereby saving the internal space.

(3) The heat generated by the cooling chip is conducted to the heater. Further, the airflow generated by the heat-dissipating fan of the electronic device can be used to dissipate the heat. Therefore, it is unnecessary to provide an additional heat-dissipating fan, thereby reducing the production cost.

(4) The heater of the cooling device is provided outside the housing. Thus, the heat dissipated may not affect the interior of the housing directly.

(5) The heat-dissipating, efficiency of the present invention is better, and thus the high temperature generated in the housing can be reduced efficiently.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electronic device having a heat-dissipating mechanism, comprising:
a housing provided with an intake hole and a plurality of exhausting holes, the interior of the housing being provided with a heat-dissipating fan to correspond to the intake hole; and
a cooling device, comprising:
a cooling chip having a cold end and a hot end;
at least one cooler connected to the cold end of the cooling chip, the cooler being provided at one side of the heat-dissipating fan along the direction of airflow generated by the heat-dissipating fan; and
at least one heater connected to the hot end of the cooling chip, the heater being located outside the housing to correspond to the locations of the exhausting holes.

2. The electronic device having a heat-dissipating mechanism according to claim 1, wherein the heat-dissipating fan has an intake end corresponding to the intake hole of the housing and an exhausting end opposite to the intake end, the cooler is provided at one side of the heat-dissipating fan adjacent to the exhausting end and is located inside the housing.

3. The electronic device having a heat-dissipating mechanism according to claim 1, wherein the heat-dissipating fan has an intake end corresponding to the intake hole of the housing, the cooler is provided at one side of the heat-dissipating fan adjacent to the intake end and is located outside the housing.

4. The electronic device having a heat-dissipating mechanism according to claim 1, wherein the cooling device further comprises at least one first heat pipe and at least one second heat pipe, one end of the first heat pipe is connected to the cold end of the cooling chip, the other end of the first heat pipe is connected to the cooler, one end of the second heat pipe is connected to the hot end of the cooling chip, and the other end of the second heat pipe is connected to the heater.

5. The electronic device having a heat-dissipating mechanism according to claim 4, wherein one side of the housing is provided with at least one through hole corresponding to the first heat pipe, and the other end of the first heat pipe extends into the housing via the through hole.

6. The electronic device having a heat-dissipating mechanism according to claim 5, wherein the cooling device further comprises a first heat-conducting block and a second heat-conducting block, the first heat-conducting block and the second heat-conducting block are arranged at the cold end and the hot end of the cooling chip, one ends of the first and second heat pipes are connected to the first and second heat-conducting blocks respectively.

7. The electronic device having a heat-dissipating mechanism according to claim 6, wherein the cooling device further comprises a casing, the cooling chip, the first heat-conducting block and the second heat-conducting block are provided inside the casing, elastic pieces are provided between the casing of the cooling device and the first and second heat-conducting blocks with the first and second heat-conducting blocks abutting against the cold end and the hot end of the cooling chip tightly.

8. The electronic device having a heat-dissipating mechanism according to claim 4, wherein the cooling device further comprises a first heat-conducting block and a second heat-conducting block, the first heat-conducting block and the second heat-conducting block are arranged at the cold end and the hot end of the cooling chip respectively, one ends of the first and second heat pipes are connected to the first and second heat-conducting blocks respectively.

9. The electronic device having a heat-dissipating mechanism according to claim 8, wherein the cooling device further comprises a casing, the cooling chip, the first heat-conducting block and the second heat-conducting block are provided inside the casing, elastic pieces are provided between the casing of the cooling device and the first and second heat-conducting blocks with the first and second heat-conducting blocks abutting against the cold end and the hot end of the cooling chip tightly.

10. The electronic device having a heat-dissipating mechanism according to claim 1, wherein the cooling device further comprises a casing, the cooling chip is arranged in the casing, a support is provided between the casing of the cooling device and the housing, thereby supporting the casing of the cooling device.

11. The electronic device having a heat-dissipating mechanism according to claim 1, wherein the cooler is a metallic net.

12. The electronic device having a heat-dissipating mechanism according to claim 1, further comprising an adjusting device connected to the cooling device.
